(19) United States
(12) Patent Application Publication
(10) Pub. No.: US 2026/0197954 A1
(43) Pub. Date: Jul. 9, 2026

(54) Hinged Device

(71) Applicant: Microsoft Technology Licensing, LLC, Redmond, WA (US)

(72) Inventors: Tung Yuen LAU, Hong Kong (CN); Mika Martti YLITALO, Shoreline, WA (US); Blair M KENT, Camas, WA (US); Amit KAISTHA, Coppell, TX (US); Devin CAPLOW-MUNRO, Seattle, WA (US); Eric WITT, Redmond, WA (US)

(73) Assignee: Microsoft Technology Licensing, LLC, Redmond, WA (US)

(21) Appl. No.: 19/134,176

(22) PCT Filed: Dec. 23, 2022
(86) PCT No.: PCT/CN2022/141283

§ 371 Date: May 29, 2025

(51) Int. Cl. H05K 5/02; G01B 21/22; G06F 1/16

(52) U.S. Cl. CPC H05K 5/0226; G01B 21/22; G06F 1/1681

(57) ABSTRACT

The description relates to hinged devices, such as hinged computing devices. One example can include a first portion including a display and a second portion including an input device. This example can also include a hinge assembly rotationally securing the first and second portions through a range of angular orientations and a sensor positioned relative to the hinge assembly and configured to sense relative linear positions of the hinge assembly that correspond to angular orientations of the first and second portions.

### BACKGROUND

Many computer form factors such as smart phones, tablets, and notebook computers can provide enhanced functionality by folding for storage and opening for use. For instance, the folded device is easier to carry and the opened device offers more input/output area.

### SUMMARY

This patent relates to hinged devices, such as hinged computing devices. One example can include a hinge assembly rotationally securing first and second device portions through a range of angular orientations. A sensor positioned relative to the hinge assembly can be configured to sense relative linear positions of the hinge assembly that correspond to angular orientations of the first and second portions.

This example is intended to provide a summary of some of the described concepts and is not intended to be inclusive or limiting.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. Further, the left-most numeral of each reference number conveys the figure and associated discussion where the reference number is first introduced. Where space permits, elements and their associated reference numbers are both shown on the drawing page for the reader's convenience. Otherwise, only the reference numbers are shown.

FIGS. 1A-1C, 2A, 2B, 3A, 3B, 4A, 4B, 7, 8A, and 8B show perspective views of example devices in accordance with some implementations of the present concepts.

FIGS. 2C, 4D-4F, 5A, 5B, 6A, and 6B show exploded perspective views of example devices in accordance with some implementations of the present concepts.

FIGS. 2D, 3C, 4C, 9A, and 9B show elevational views of example devices in accordance with some implementations of the present concepts.

FIG. 2E shows an exploded elevational view of an example device in accordance with some implementations of the present concepts.

### DESCRIPTION

The present concepts relate to devices, such as computing devices employing hinge assemblies that can allow rotation of first and second device portions through a range of orientations (e.g., relative angles or angular orientations). Traditionally, angular orientation has been determined by sensing rotation of the device portions around the hinge assembly. However, this angular sensing tends to be inaccurate and unreliable. In contrast, the present concepts involve hinge assemblies that include a member that moves linearly when the first and second portions are rotated. A sensor can be employed to sense this linear movement of the member. The sensed position of the member can be mapped to the angular orientation of the first and second portions. This linear sensing is much more reliable than traditional angular sensing.

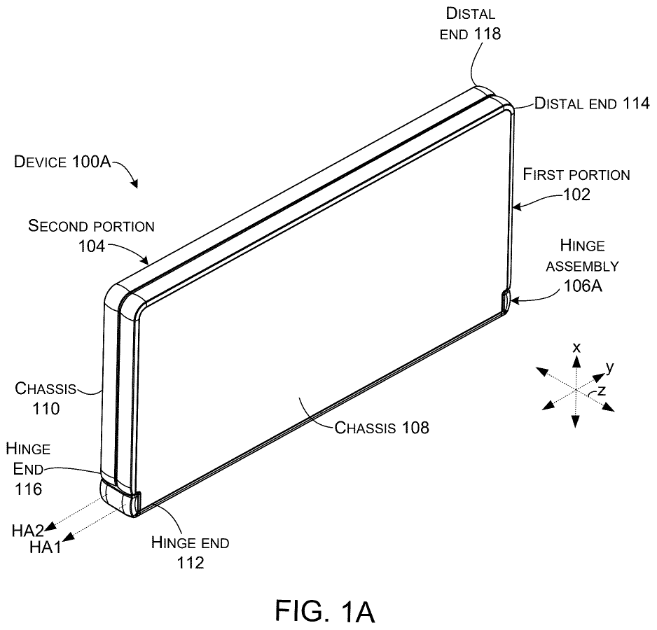

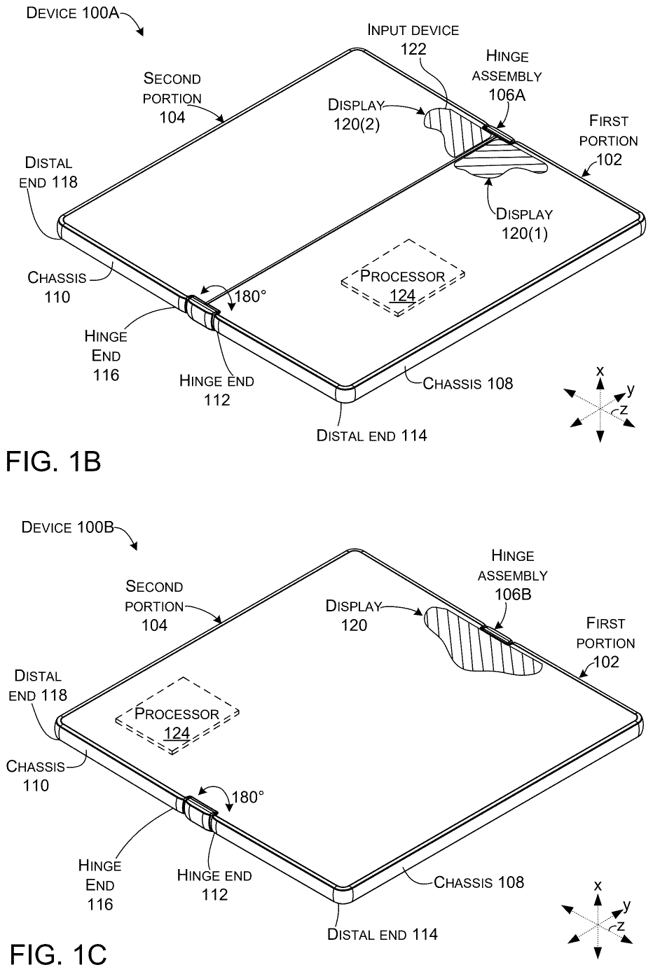

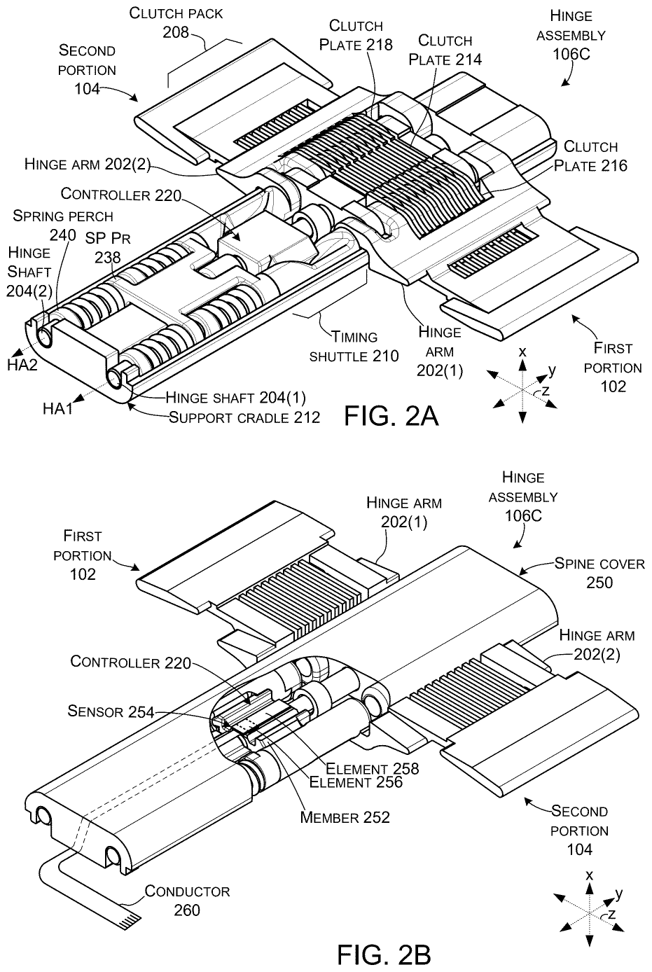

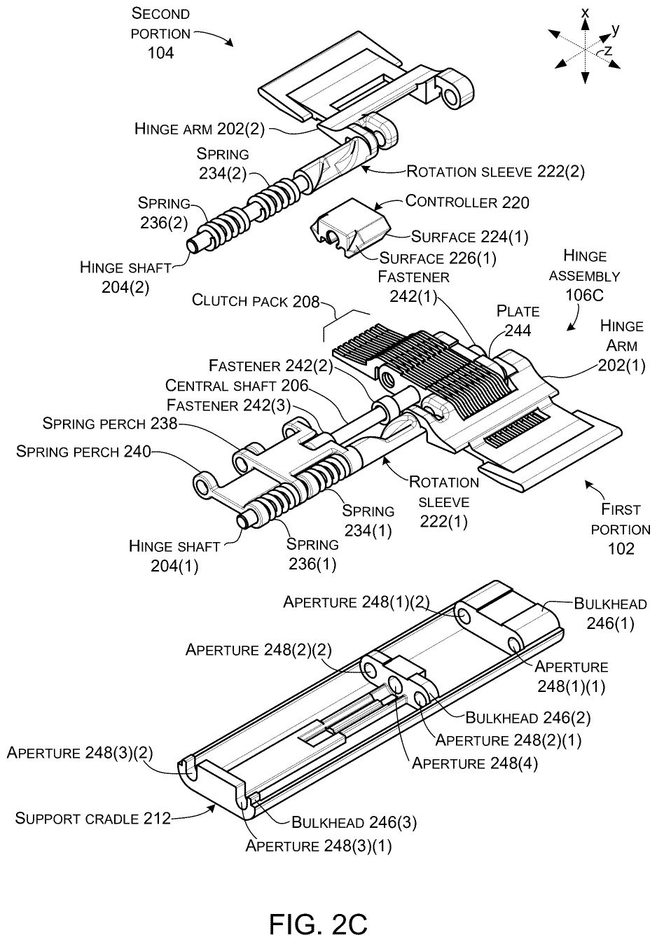

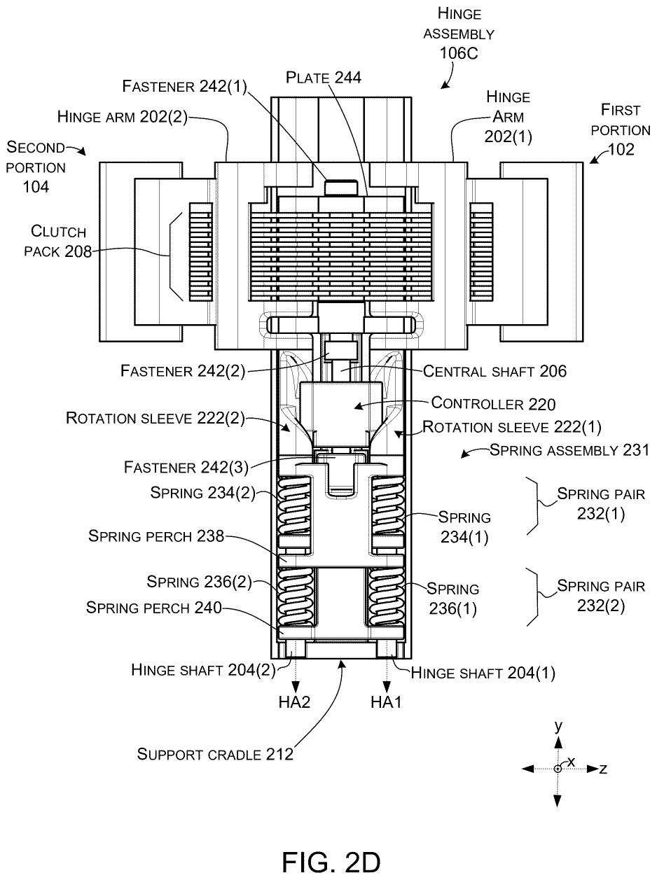

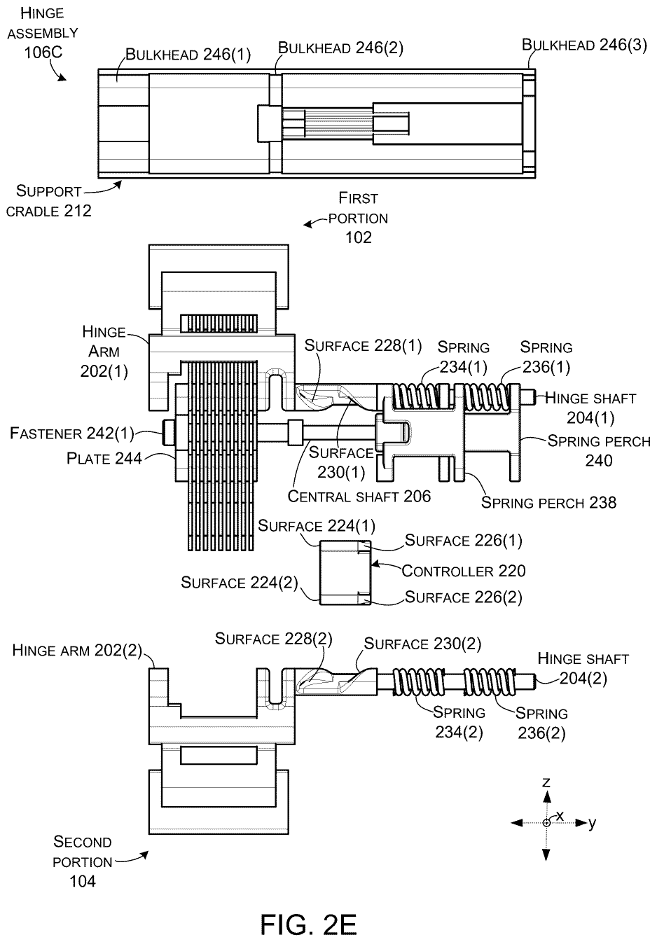

Introductory FIGS. 1A-1C collectively show two example device configurations. Device 100A includes first and second portions 102 and 104 that are coupled by a hinge assembly 106A to allow rotation through a range of orientations (e.g., relative angles). As will be described below starting relative to FIG. 2A, the present implementations have the capability to (indirectly) sense the orientation of the first and second portions.

The first portion 102 includes a housing or chassis 108 and the second portion 104 includes a housing or chassis 110. The first portion 102 extends from a hinge end 112 to a distal end 114 and the second portion 104 extends from a hinge end 116 to a distal end 118. The device can include displays 120 and/or input devices 122. The device also includes a processor 124. While a single processor is illustrated, the device can include multiple processors, such as a central processing unit for general processing functions, a graphics processing unit for powering the displays, and/or microcontrollers for accomplishing specific processing functions, such as mapping sensor data to hinge angle (e.g., angular orientation). The processor can also use the mapped hinge angle for various other functions. For instance, the processor may control whether (and how) content is presented on the display based upon the mapped hinge angle.

The hinge assembly 106A defines hinge axes (HA). Note that the illustrated configuration includes two hinge axes. The first portion rotates around hinge axis one (HA1) and the second portion rotates around the second hinge axis (HA2). The present concepts also work with a single hinge axis. The present concepts also work with complex hinges where the hinge axis moves during rotation rather than remaining stationary.

FIG. 1A shows device 100A in a closed or approximately zero-degree orientation. As used herein the approximately zero-degree orientation can be exactly zero degrees and can also include orientations within +/− about three degrees (e.g., −3 degrees to +3 degrees). FIG. 1B shows a first variation of device 100A in an open orientation of about 180 degrees and FIG. 1C shows a second variation of device 100B in an open orientation of about 180 degrees. As used herein the approximately 180-degree orientation can be exactly 180 degrees and can also include approximate orientations within +/− about five degrees (e.g., 175-185 degrees).

FIG. 1B shows example device 100A with a first display 120(1) positioned on the chassis 108 of the first portion 102 and a separate and distinct second display 120(2) positioned on the chassis 110 of the second portion 104. The displays 120(1) and 120(2) abut at the hinge assembly 106A in the 180-degree orientation. In this case, the displays 120 are touch sensitive displays. Thus, one or both of the displays 120(1) and 120(2) can also function as the input device 122. In other configurations, one of the displays could be replaced with a dedicated input device, such as a keyboard and/or trackpad.

FIG. 1C shows example device 100B with a single display 120 spanning from the first portion 102 over the hinge assembly 106B to the second portion 104. The single display 120 can be a (touch sensitive) flexible display that can bend at the hinge assembly 106B when the device is closed. The hinge assembly 106B can provide space for an enlarged minimum bend radius for the display 120 (e.g., teardrop shape) over the hinge assembly 106B as the device 100B is closed to reduce potential damage, such as crimping of the flexible display. In both of the illustrated configurations of FIGS. 1B and 1C, portions of the hinge assembly 106 are visible at the edges of the device. In other implementations, the hinge assembly 106 may not be readily visible.

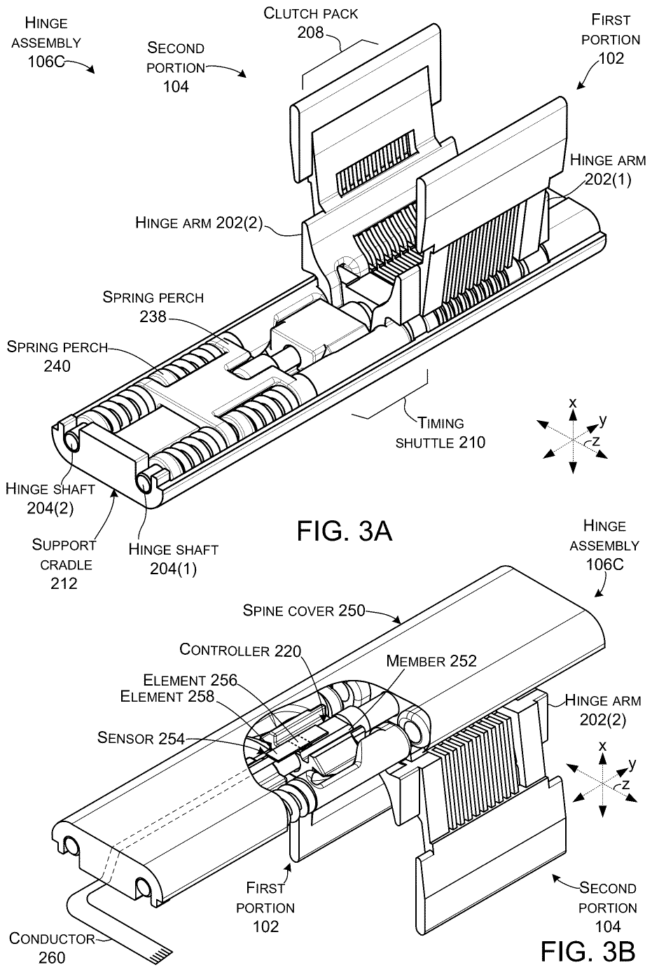

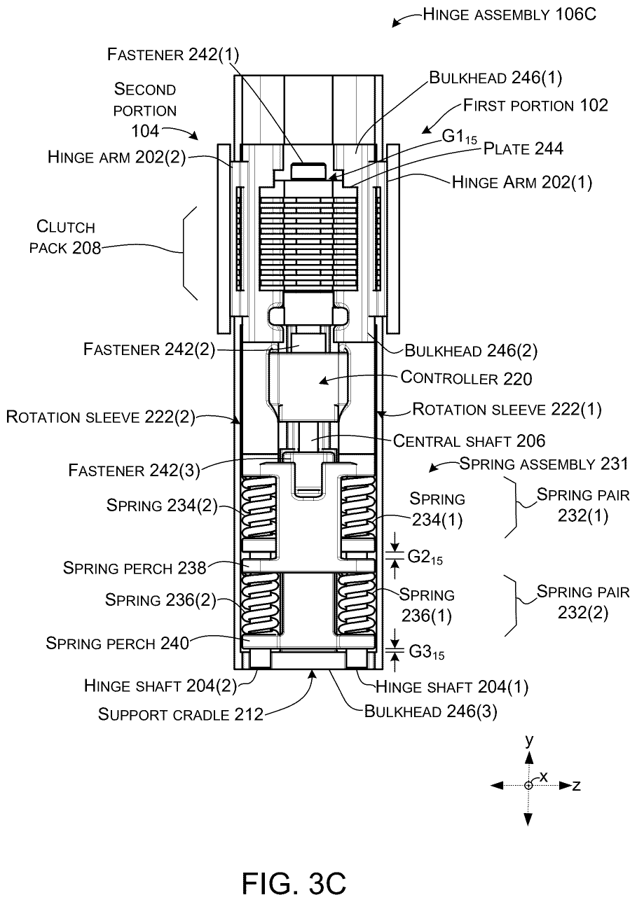

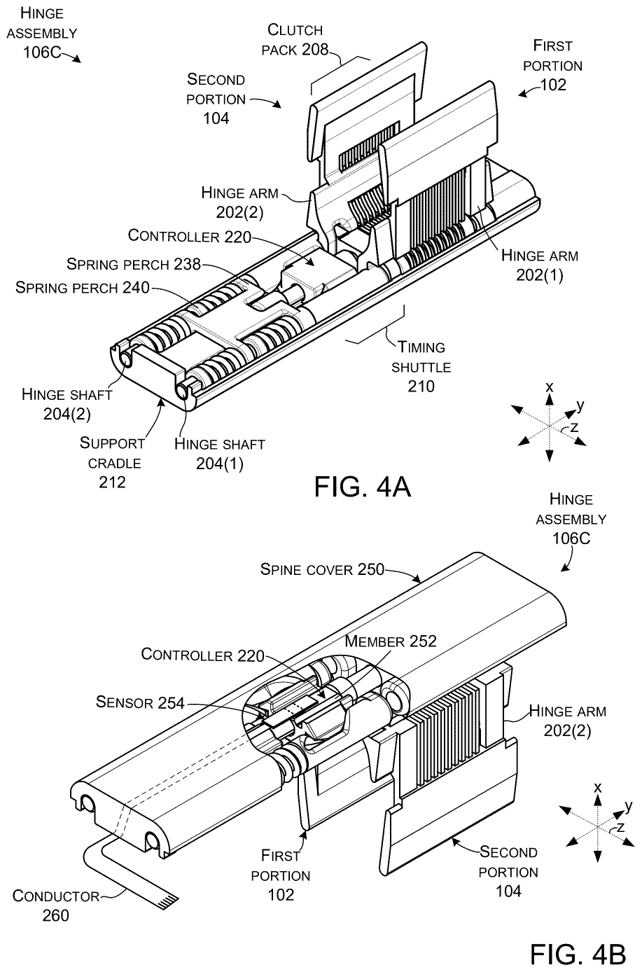

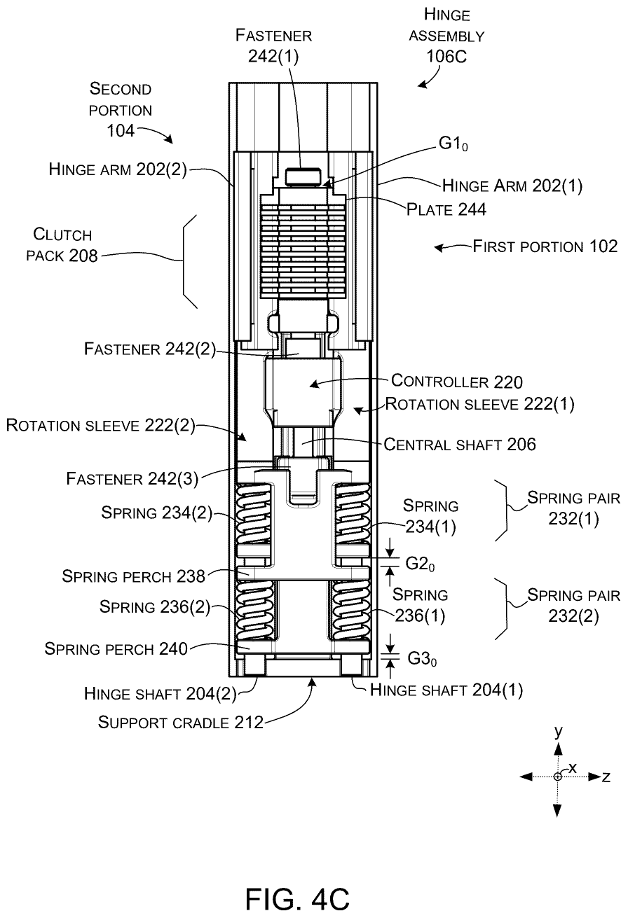

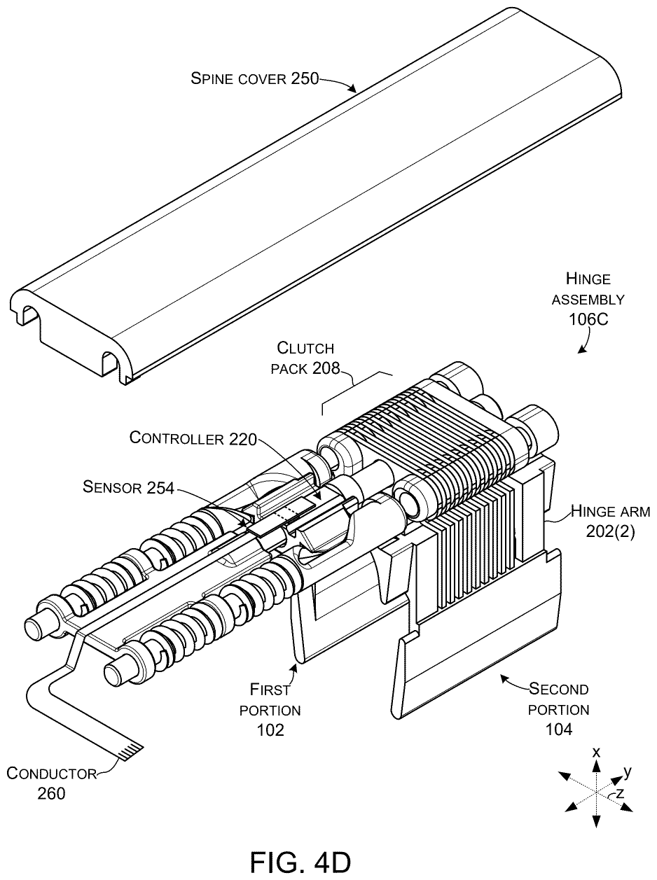

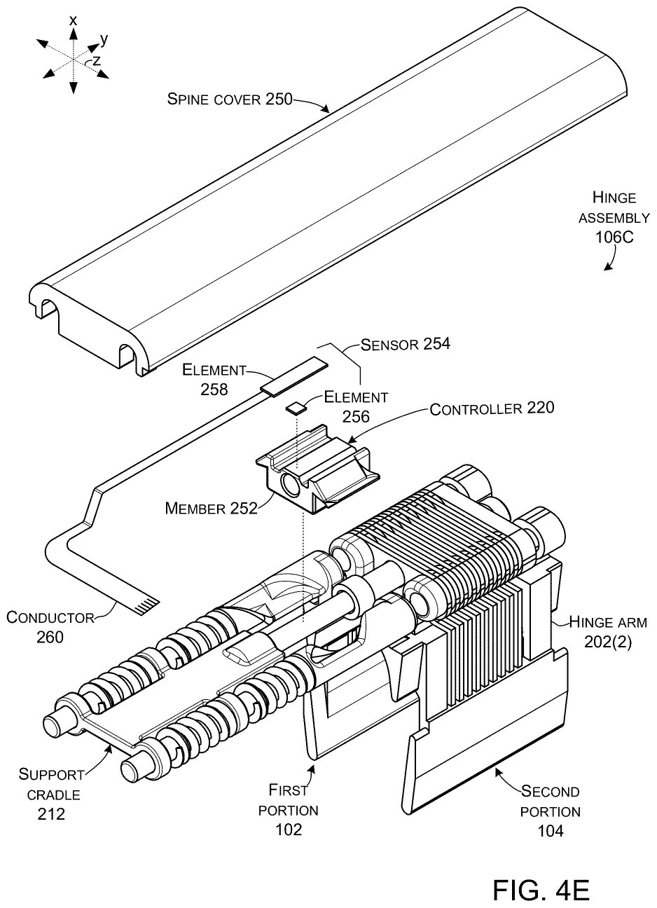

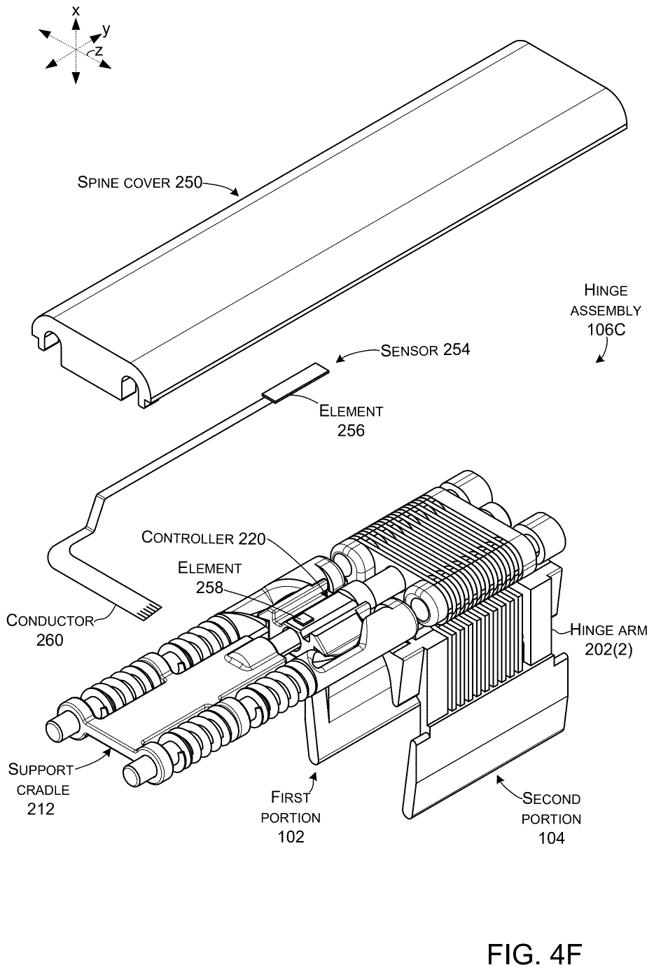

FIGS. 2A-2E, 3A-3C, and 4A-4F collectively show details of an example hinge assembly 106C. FIGS. 2A-2E show the hinge assembly in a 180-degree orientation, FIGS. 3A and 3B show the hinge assembly in a 15-degree orientation, and FIGS. 4A and 4B show the hinge assembly in a closed or zero-degree orientation. FIG. 2A is a perspective ‘top side’ view and FIG. 2B is a corresponding ‘bottom side’ view. FIG. 2C is an exploded perspective view that corresponds to FIG. 2A. FIG. 2D is an elevational view and FIG. 2E is a corresponding exploded elevational view. FIGS. 3A and 3B are similar to FIGS. 2A and 2B but at the 15-degree orientation. FIG. 3C is an elevational view at the same orientation. FIGS. 4A and 4B are similar to FIGS. 2A and 2B as well as 3A and 3B, but at a closed orientation. FIGS. 4D-4F are exploded perspective views that correspond to FIG. 4B.

Note that in this implementation, the range of orientations of the hinge assembly is 0 degrees to 180 degrees. Other implementations can have smaller or larger ranges. For instance, the hinge assembly could be configured to rotate from 0 to 100 degrees or 0 to 360 degrees, among other configurations.

In this case, the hinge assembly 106C includes hinge arms 202, hinge shafts 204, a central shaft 206, a clutch pack 208, a timing shuttle 210 (FIG. 2A), and a support cradle 212. (Not all elements are designated in each figure, but the elements listed in this paragraph are designated at least in FIG. 2C unless noted otherwise). The clutch pack 208 can include central clutch plates 214 (FIG. 2A) that are arranged with first side clutch plates 216 (FIG. 2A) and second side clutch plates 218 (FIG. 2A). (Only representative clutch plates are labelled to avoid clutter on the drawing page). The timing shuttle 210 can include controller 220 and rotation sleeves 222. The controller 220 can define surfaces 224 and 226 and rotation sleeves 222 can define contact surfaces 228 and 230 (FIG. 2E). This hinge assembly 106 can also include a spring assembly 231 in the form of first and second spring pairs 232 (FIG. 2D) that entail springs 234 and 236 and spring perches 238 and 240, fasteners 242 and plates 244. The support cradle 212 can define bulkheads 246 that define apertures 248. A backside or spine of the hinge assembly can be protected by a spine cover 250 (FIG. 2B) that engages the support cradle 212.

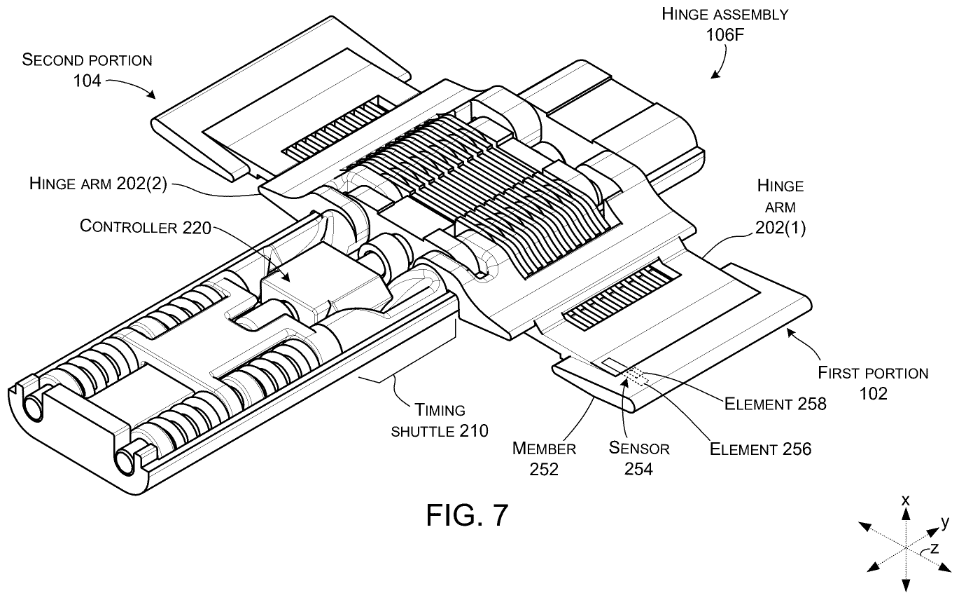

Hinge assembly 106C further includes a member 252 that moves linearly in a manner that corresponds to rotational orientation (e.g., angle) of the first and second portions 102 and 104. In this example, the member 252 is manifest as the controller 220. In an alternative example explained below relative to FIG. 7, the hinge arms 202 can function as the member 252.

A sensor 254 (FIG. 2B) can sense the linear movement of the member 252 to identify the corresponding angle of the first and second portions. In this case, the sensor 254 includes a first (sensor) element 256 that is positioned on the member 252 and a second (sensor) element 258 that is positioned proximate to the member 252. Stated another way, the first element 256 can travel with the member 252 and the second element 258 can be fixed in place (e.g., fixed position) to sense the relative movement (e.g., position) of the first element 256 and hence the member 252. The sensor can be coupled to the processor (124, FIG. 1B) by conductor 260.

The sensor 254 and its elements 256 and 258 may be more easily visualized in the exploded view of FIG. 4E. The sensor provides a technical solution of sensing the linear position (of a portion) of the member 252. The linear position of the (portion of) the member corresponds to an angle of the first and second portions. This technical solution is more accurate than traditional solutions that attempt to directly sense rotation of the first and second portions, such as by sensing rotation around a hinge axis. Further, this technical solution positions the sensor 254 at a location on the device, in this case the spine, where space is available for the sensor and the sensor is protected between the support cradle 212 and the spine cover 250. Also, the present linear sensing is effective for hinge assemblies where the first and second portions rotate around a path or trajectory rather than a fixed axis. Traditional rotational sensors cannot accommodate such hinge configurations.

From another perspective, the present concepts provide a technical solution of improved accuracy of sensing the relative position of the foldable device because the sensed movement is a linear function of the angle of rotation. This linear function allows a more accurate determination of the angular position than traditional solutions. The accuracy determination is higher because the movement is linearly related in contrast to directly determining the angular position which may be a less reliable non-linear relationship over the range of rotation.

In the illustrated configuration, the hinge shafts 204 are coextensive with hinge axes (HA) of the hinge assembly 106. The hinge arms 202 are positioned on the hinge shafts 204. The hinge arms 202(1) and 202(2) are also secured to the first and second portions 102 and 104, respectively. In some cases, the hinge arms 202 are fixedly secured to the first and second portions. In other cases, the hinge arms 202 can be moveably secured to the first and second portions. As used here, ‘moveably secured’ means that limited linear movement (e.g., sliding or translation) and/or limited rotational movement (e.g., pivoting) can occur between the hinge arms and the first and second portions. In this latter configuration, the motion of the first and second portions is driven or determined by the hinge arm rotation around the hinge axes. In an alternative implementation show in FIG. 7 this sliding motion between the hinge arm and the first and second portions can be sensed by sensor 254 to determine the device orientation. The present implementations provide a technical solution that senses the linear movement of the member and accurately functions with each of the above listed interactions between the hinge assembly and the first and second portions.

The clutch pack 208 spans across the hinge arms 202 and the central shaft 206. The hinge shafts 204 can be coextensive with hinge axes (HA) defined by the hinge assembly 106C. Hinge arm 202(1) is secured to the first portion 102 (indicated generally, shown with specificity in FIGS. 1A-1C) and hinge arm 202(2) is secured to the second portion 104 (indicated generally, shown with specificity in FIGS. 1A-1C). Hinge arm 202(1) is positioned in non-rotating relation with rotation sleeve 222(1) and hinge arm 202(2) is positioned in non-rotating relation with rotation sleeve 222(2). The clutch pack 208 provides a variable friction engine. The amount of rotational friction (e.g., frictional torque) produced by the clutch pack relates to how much force is applied to squeeze the clutch plates 214, 216, and 218 together (e.g., more squeezing force results in the clutch pack generating more frictional torque).

The clutch pack 208 is captured along the central shaft 206 between plate 244 and bulkhead 246(2). The plate 244 is retained on the central shaft 206 by fastener 242(1). In some implementations, individual fasteners 242 can be manifest as a nut that is threaded and is positioned on a threaded region of the central shaft 206 to allow adjustability in the y reference direction (e.g., parallel to the hinge axes). In other cases, individual fasteners 242 can entail a collar that is positioned at a desired location along the central shaft 206 and welded or otherwise locked in place.

The controller 220 is positioned on the central shaft 206. The rotation sleeves 222 are positioned on the hinge axes HA1 and HA2 (e.g., on the hinge shafts 204). Interaction of the controller's surfaces 224 and 226 with the contact surfaces 228 and 230 of the rotation sleeves substantially synchronizes rotation of the first and second portions 102 and 104. Thus, for example, 40 degrees of rotation of the first portion produces 40 degrees of simultaneous (and opposite) rotation of the second portion (+/− up to several degrees due to component tolerances). In this case, the contact surfaces 228 and 230 of the rotation sleeves 222 are curved surfaces.

The controller 220 follows the curved contact surfaces 228 and 230 as it moves along the central shaft 206 responsive to rotation of either the first and/or second portions. In this example, the surfaces 228 and 230 are curved with a constant pitch around the hinge axes in the form of helical contact surfaces (e.g., the contact surfaces are helically curved).

Thus, the linear position of the controller 220 along the central shaft 206 is determined by the interaction of the controller 220 with the rotation sleeves 222. In turn, the position of the rotation sleeves 222 is determined by the orientation of the hinge arms 202, which are in turn (slideably) secured to the first and second portions 102 and 104. Thus, the curved contact surfaces 228 and 230 move the controller 220 along the central shaft 206 corresponding to rotation of the first and/or second portions by an amount (e.g., linear distance) determined by the pitch of the curved contact surfaces 228 and 230 and the extent of the rotation. The sensor 254 can sense the position of the controller 220 by sensing the relative location of element 256 (which moves with the controller 220) relative to element 258 which is fixed in place. This movement of the controller 220 and element 256 relative to element 258 can be evidenced by comparing FIGS. 2B, 3B, and 4B. Note that in FIGS. 2B, 3B, and 4B, element 256 is shown in ghost because it underlies and is obscured by element 258.

In this implementation, spring perches 238 and 240 overlap with one another and spring perch 240 extends under spring perch 238 and is secured relative to fastener 242(3) and indirectly to controller 220. The spring perches 238 and 240 and springs 234 and 236 are positioned on hinge shafts 204. The spring 234 and 236 are captured between the overlapping portions of the spring perches 238 and 240. The hinge shafts 204 are positioned in apertures 248(1)-248(3). The controller 220 is positioned on the central shaft 206. The controller 220 is positioned between fastener 242(2) and fastener 242(3) on the central shaft 206. Fastener 242(3) is associated with spring perch 238 which also supports the central shaft 206. As noted above, the controller position is determined by the rotation angle of the hinge shafts. The controller in turn bears against fastener 242(2) near zero degrees, which then releases the spring load from the clutch pack 208 via the central shaft 206.

This example hinge assembly 106C functions as a friction hinge that creates resistance to rotation (e.g., frictional torque) that can keep the first and second portions at an orientation set by the user. In this case, the amount of friction provided by the hinge assembly is related to the orientation of the device (e.g., at some orientations the hinge assembly provides a relatively high amount of friction (e.g., resistance to rotation or ‘frictional torque’) and at other orientations the hinge assembly provides a relatively low amount friction (e.g., resistance to rotation or ‘frictional torque’)). The 180-degree orientation of FIGS. 2A-2E represents a relatively high friction orientation. The zero-degree orientation of FIGS. 4A-4F represents a relatively low friction orientation. The 15-degree orientation of FIGS. 3A-3C represents a transition between the relatively low friction state of 0 degrees to 15 degrees and the relatively high friction state of 15 degrees to 180 degrees. Other implementations can employ different transition orientations, such as 10 degrees or 20 degrees, for example.

Looking at the relatively high friction orientation of FIGS. 2A-2E, first and second spring pairs 232 are biasing spring perch 240 away from the clutch pack 208 in the −y reference direction (e.g., toward the bottom of the drawing page). In turn, spring perch 240 is secured relative to fastener 242(2) and thus is biasing fastener 242(3) away from the clutch pack 208. Fastener 242(3) is secured to central shaft 206 and is thus biasing the central shaft 206 in the same direction. Note that while fastener 242(3) is identified as a distinct component, this fastener can also be viewed as a subcomponent of spring perch 240. In this example, the fastener 242(3) is externally threaded and is received by internal threads of spring perch 240 to allow length adjustment in the y direction of the spring perch 240/fastener 242(3) assembly.

The central shaft 206 extends through the clutch pack 208 and plate 244 and is secured relative to fastener 242(1). The bias on the fastener 242(1) is thus transferred to the plate 244 and then the clutch pack 208 by the plate. The opposite end of the clutch pack 208 is retained by bulkhead 246(2). Thus, the bias imparted by the plate 244 toward the bulkhead 246(2) compresses the clutch pack 208 and thereby creates increased resistance to rotation between individual clutch plates 214, 216, and 218. This increased resistance to rotation is configured to cause the device portions 102 and 104 to maintain this orientation unless acted upon by an external force (e.g., the user).

Note that in this configuration, while the first and second spring pairs 232(1) and 232(2) are sequentially arranged along the hinge shafts 204, the bias created by each spring pair 232 is transferred directly to the spring perch 240 and the central shaft 206 (e.g., the bias from second spring pair 232(2) is not imparted on first spring pair 232(1) and then to the central shaft through the first spring pair 232(1)). Thus, in this configuration despite the first and second spring pairs 232 being physically sequentially arranged along the hinge shafts 204, the first and second spring pairs functionally deliver their respective bias to the central shaft 206 as though they were organized in parallel (e.g., arranged side by side and directly in contact with the central shaft). This arrangement allows the first and second spring pairs to be sequentially arranged along the hinge shafts (e.g., in a relatively long and thin manner) yet perform as though they were arranged side by side (e.g., in a short and bulky manner).

Note further that while the springs 234 and 236 are positioned on the hinge shafts 204, the spring force (e.g., bias) generated by the springs is controlled by controller 220. In the relatively low frictional torque range from zero degrees to 15 degrees, the spring bias is transferred to the controller 220. In the relatively high frictional torque range from 15 degrees to 180 degrees, the spring bias can be transferred to the clutch pack 208. In the transition between high and low frictional torque the spring bias can be shared by the controller and the clutch pack.

In an instance where the user wants to close the device, such as from the 90-degree orientation, the user can exert a force on the first portion 102 and/or second portion 104 toward one another (e.g., in a closing direction) sufficient to overcome the resistance to rotation (e.g., frictional torque) created by the clutch pack 208. In such a case, the controller's surfaces 224 and 226 interact with the helical contact surfaces 228 and 230 of the rotation sleeves 222 to cause equal rotation of both the first and second portions. Note that the pitch of contact surfaces 228(1) and 228(2) as well as 230(1) and 230(2) are essentially equal to promote equal rotation around the two hinge shafts and to avoid binding. Stated another way, in order for either of the rotation sleeves 222 to be rotated around the hinge axes (e.g., hinge shafts 204) relative to the controller 220, the interaction of the controller's surfaces 224 and 226 with the helical contact surfaces 228 and 230 causes the controller 220 to move along the central shaft 206 in the y reference direction (e.g., parallel to the central shaft 206). The linear position of the controller 220 in the y reference direction (e.g., parallel to the hinge axes) is determined by sensor 254 and is mapped to the corresponding hinge angle.

The movement of the controller 220 in the y reference direction comes with associated interaction of its surfaces 224 and 226 with contact surfaces 228 and 230 of the other rotation sleeves 222 and forces simultaneous and equal rotation of each rotation sleeve 222 due to the helical shape of contact surfaces 228 and 230. In some configurations, the rotation can be exactly simultaneous and equal. Other configurations can allow a few degrees variation, such as up to +/− ten degrees associated with design tolerances and associated slack in the system. Either way, during this rotation, the frictional torque provided by the clutch pack 208 can remain relatively steady or at least relatively high compared to the relatively low state described below relative to FIGS. 4A-4F.

FIGS. 3A-3C collectively show the hinge assembly 106C after simultaneous and equal rotation of the first and second portions from the 180-degree orientation to a 15-degree orientation. The rotation of the first and second portions produces rotation of the rotation sleeves 222 and associated linear movement of the controller 220 toward the clutch pack 208. The sensor 254 tracks the linear movement of the controller 220 via the position of element 256, which moves with the controller, relative to element 258, which is fixed in place.

In the illustrated orientation the controller 220 has moved toward the clutch pack 208 until the controller 220 contacts fastener 242(2). Contact with the fastener 242(2) blocks further movement of the controller 220 along the central shaft 206. In order for the controller 220 to move farther toward the clutch pack 208 (as the result of continued rotation of the first and second portions 102 and 104 toward one another) the controller moves the central shaft 206 with it. Moving the central shaft 206 will entail overcoming the bias created by the springs 234 and 236 on the central shaft toward the spring assembly 231. In this implementation, such movement of central shaft 206 starts at 15 degrees and continues to zero degrees. This central shaft movement is relatively small and may be difficult to perceive in the drawings. However, the movement has large effects on the function of the hinge assembly 106. From another perspective, slight movement of the shuttle between 0 degrees and 15 degrees can significantly change the hinge torque.

Three gaps (G) are shown in FIGS. 3C and 4C for comparison to aid the reader to appreciate the movement of the central shaft 206. The first gap G1 relates to the amount of space between fastener 242(1) and plate 244. The second gap G2 relates to the amount of space between spring perch 238 and spring perch 240 and reflects the extent of the compression of the first spring pair 232(1). The third gap G3 relates to the amount of space between spring perch 240 and bulkhead 246(3) and reflects the extent of the compression of the second spring pair 232(2). These gaps remain relatively steady in the high friction condition between the 180-degree orientation of FIGS. 2A-2E and the 15-degree orientation of FIGS. 3A-3C. Stated another way, G1 is zero in the high friction condition (e.g., fastener 242(1) is in contact with plate 244 and thus spring force is transferred to the clutch pack). The 15-degree orientation represents changing or transition conditions that are distinguishable in the zero-degree orientation. Each of these gaps G expands from the 15-degree orientation of FIGS. 3A-3C to the zero-degree orientation of FIGS. 4A-4F.

FIGS. 4A-4F show the hinge assembly 106C in the zero-degree orientation. At this point, the controller 220 has contacted fastener 242(2) and overcome the bias of the spring pairs 232 to move the central shaft 206 upwardly (e.g., in a direction opposite to the spring bias). This upward movement (e.g., in the +y direction) can be reflected in gap one G1₀ which is larger than G1₁₅ at the 15-degree orientation and shows that the compressive force on the clutch pack 208 that is created by the bias of the spring pairs 232 is decreased. Thus, the resistance to rotation (e.g., frictional torque) created by the clutch pack 208 is reduced. This allows the first and second portions to be rotated with less force than is required at orientations from 15 degrees and upwards. Stated another way, the reduced compressive force on the clutch pack allows the user to more easily open the device from the zero-degree (e.g., closed orientation) than would be required without reducing the compressive force on the clutch pack 208.

The upward movement of the central shaft 206 (e.g., away from the spring assembly 231) has also pulled spring perch 240 upwardly as represented by the increase in gap G2₀ (compared to G2₁₅) and gap G3₀ (compared to G3₁₅). The upward movement of spring perch 240 compresses first and second spring pairs 232 and thus stores potential energy in the spring pairs. This stored potential energy can subsequently be released as kinetic energy that automatically opens or pops-up the device from the closed orientation. For instance, the device could include a lock that can hold the device at the zero-degree orientation when the user closes it. When the user once again wants to open the device and unlocks the lock, the pop-up force can automatically force the first and second portions apart to the 15-degree orientation, where the potential energy is converted to kinetic energy and the clutch pack 208 is once again compressed and increases the resistance to rotation (e.g., frictional torque) for continued opening to higher (e.g., greater than 15 degree) orientations.

The controller 220 operates in concert with the spring assembly 231, the rotation sleeves 222, the hinge shafts 204, the central shaft 206, and the clutch pack 208 to provide orientation specific frictional torque. Low angles (e.g., approaching and including closed) have low frictional torque so the user can easily move the first and second portions, such as with one hand. Higher angles, such as starting at 15 degrees and progressing to fully open provide increased frictional torque to hold the device in whatever orientation the user sets. The controller 220 affects the frictional torque based upon its linear position along the y reference axis and this linear position is sensed by sensor 254.

As introduced above, the hinge assembly 106C includes clutch pack 208 that functions as a clutch-pack style friction engine. The hinge assembly 106 also includes two or more spring pairs 232 for compressing the clutch pack 208 to generate frictional torque. Further, fastener 242(1) functions as an adjustment nut for tuning the magnitude of compressive force applied on the clutch pack 208 for adjustable frictional torque. Also, the timing shuttle 210 is manifest as a helical timing shuttle with a sliding component (e.g., controller 220) interacting with helical contact surfaces 228 and 230. The controller 220 provides a mechanism for engaging/disengaging the clutch pack 208 at a selected hinge open angle (e.g., 15 degrees in this implementation). The surfaces 228 and 230 of the rotation sleeves 222 are helical contact surfaces that have a constant and matching pitch.

Engagement between the controller 220 and the helical contact surfaces 228 and 230 of the rotation sleeves 222 produces a rotational force applied to both the first and second portions producing linear movement of the controller and resultant equal rotation of both rotation sleeves 222 and hence both hinge arms 202 and thus each of the first and second portions 102 and 104. Stated another way, if the user attempts to decrease the orientation of the first portion, the user imparts a rotational force on rotation sleeve 222(1). In this configuration, in order for the rotation sleeve 222(1) to rotate, the controller 220 has to move in the y reference direction (e.g., along the central shaft 206). This movement of the controller (e.g., the linear position of the controller) is sensed by sensor 254.

In order for the controller 220 to move along the central shaft 206, equal but opposite rotation has to occur on second rotation sleeve 222(2). Thus, the rotation imparted on the first portion causes equal and simultaneous rotation of both rotation sleeves 222 and hence both the first and second portions but in opposite directions. Thus, if the first portion rotates counter-clockwise, the second portion simultaneously rotates an equal amount clockwise. This ensures that both portions stay timed (e.g., symmetric) with one another. This angular orientation of the first and second portions is directly determined by the linear position of the controller 220, which is identified by sensor 254.

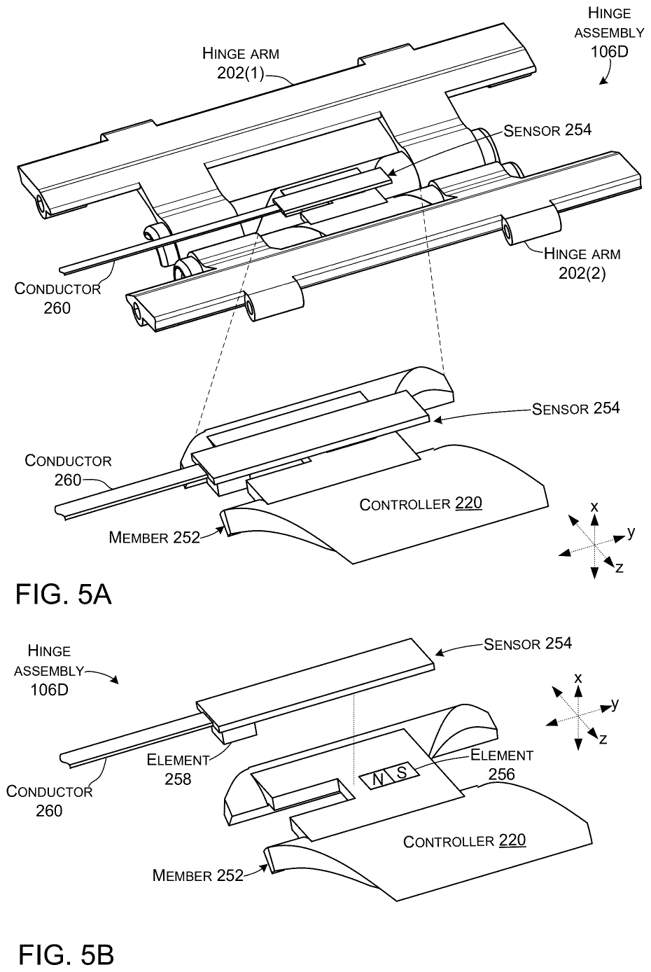

FIGS. 4B, 4D, 4E, and 4F show details of the sensor 254. In this case, sensor element 256 is secured to controller 220. For instance, the sensor element 256 could be glued or soldered to the controller 220. In an alternative configuration, sensor element 256 could be embedded in the controller, such as by molding the controller with the sensor element positioned in the mold or by 3D printing the sensor element 256 on or in the controller. Sensor element 258 can be fixed in position relative to the controller 220. For instance, sensor element 258 can be positioned on or suspended from the cradle 212 or the spine cover 250 proximate to the sensor element 256. This allows sensor element 258 to sense the linear position of sensor element 256 and hence the linear position of controller 220. This linear position maps to a corresponding hinge angle (e.g., angle formed between the first and second portions). FIGS. 5A and 5B as well as 6A and 6B show details of other example sensor configurations.

FIGS. 5A and 5B collectively show a portion of an example hinge assembly 106D that is similar to hinge assembly 106C described above. Hinge assembly 106D includes hinge arms 202 and controller 220 that synchronize rotation of the hinge arms. The controller 220 functions as member 252 and moves linearly as the first and second portions are rotated. Sensor element 256 is manifest as a magnet that travels with the controller 220. Sensor element 258 is manifest as a Hall effect sensor. The linear motion of the controller 220 in the y reference direction changes the distance between the magnet and the Hall effect sensor. The Hall effect sensor generates a signal that is affected by the distance. The signal is used for determining a position of the controller 220 and thereby the hinge angle of the first and second portions. Note that while a Hall effect sensor is described in this specific example, other sensor types can be employed for sensing the magnetic field. Examples include anisotropic magneto-resistance (AMR), giant magneto-resistance (GMR), semiconductor magnetoresistor (SMR), and tunnel magneto resistive (TMR) types of magnetic sensors, among others.

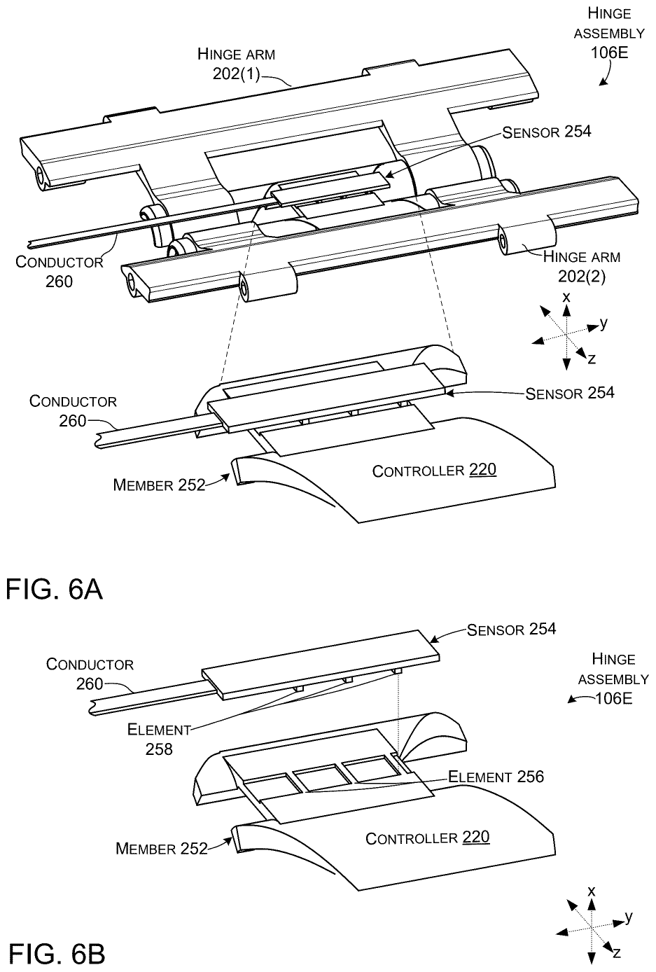

FIGS. 6A and 6B collectively show a portion of another example hinge assembly 106E that is similar to hinge assemblies 106B-106D described above. Hinge assembly 106E includes hinge arms 202 and controller 220 that synchronize rotation of the hinge arms. The controller 220 functions as member 252 and moves linearly as the first and second portions are rotated. Sensor element 256 is a comb pattern. The sensor element 256 moves with the controller 220. Linear movement of the comb pattern of sensor element 256 across the capacitive sensing pads of element 258 causes changes in capacitance between the comb pattern and each of the capacitive sensing pads. The sensor 254 measures the change in capacitance and generates a signal for determining the position of the controller 220 and therefore the hinge angle.

FIG. 7 shows another example hinge assembly 106F that is similar to hinge assembly 106C described relative to FIGS. 2A-4F. In this case, member 252 that moves linearly during hinge rotation is manifest as the first portion 102 sliding relative to hinge arm 202(1). The sensor 254 is positioned relative to the hinge arm 202(1) and the first portion 102. Element 256 is positioned on the first portion 102 and element 258 is positioned on the hinge arm 202(1). Rotation of the first and second portions is synchronized by the timing shuttle 210.

Rotation of the first portion 102 is associated with linear sliding between the first portion and the hinge arm 202(1). The sensor 254 is configured to detect this relative linear movement or relative linear position. As mentioned above, element 256 is positioned on first portion 102 and element 258 is positioned on hinge arm 202(1). Rotation of the first and second portions causes linear movement of the first portion relative to the hinge arm 202(1). This linear movement changes the position of element 256 relative to element 258. The sensor 254 can detect the relative positions of the sensor elements and map the relative positions to a corresponding angular orientation of the first and second portions.

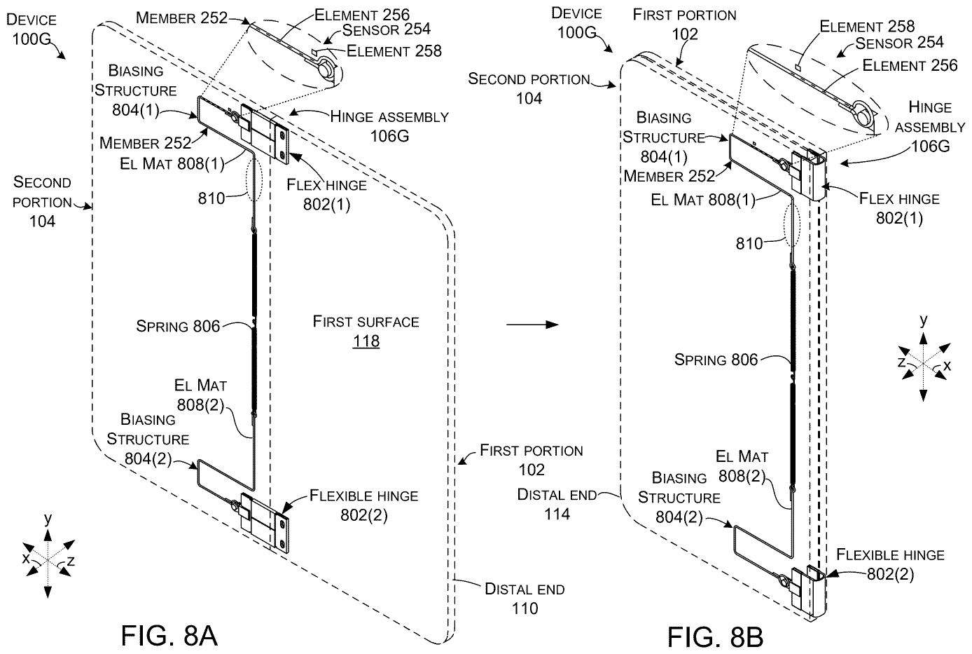

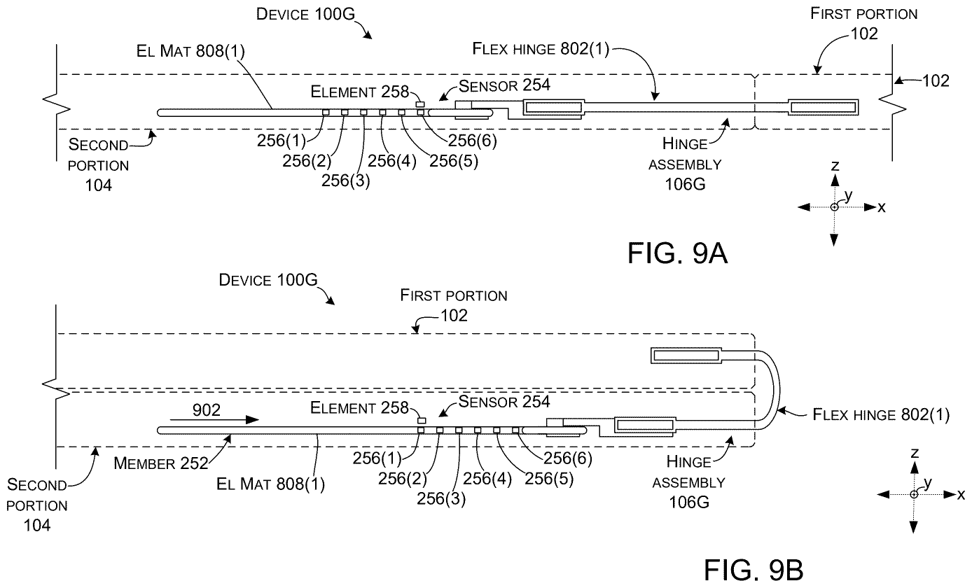

FIGS. 8A, 8B, 9A, and 9B collectively show another device 100G that includes first and second portions 102 and 104 that rotate relative to hinge assembly 106G. FIGS. 8A and 9A show the device portions in the 180-degree orientation and FIGS. 8B and 9B show the device portions in the closed orientation. In FIGS. 8A and 8B the first and second portions are shown in ghost to allow underlying components of the hinge assembly 106G to be visualized.

In this case, hinge assembly 106G includes upper and lower flexible hinges 802(1) and 802(2). The flexible hinges 802(1) and 802(2) are associated with biasing structures 804(1) and 804(2). The biasing structures 804(1) and 804(2) can bias the flexible hinges 802 into the second portion 104 such that a length of the flexible hinge in the second portion changes as the first and second portions are rotated through a range of angles. Stated another way, the biasing structure 804 can exert a force on the flexible hinge 802 into the second portion 104. This force can be overcome to varying degrees at various orientations of the first and second portions 102 and 104 so that a length of the flexible hinge interposed between the first and second portions is different at different orientations.

In this case, the biasing structures 804 share a common spring 806. The spring 806 is positioned between the two biasing structures 804(1) and 804(2). Opposing ends of the spring are indirectly connected to the biasing structures via first and second intervening elongate material 808(1) and 808(2). Stated another way, a first end of the spring 806 is connected to the first elongate material 808(1), and an opposite end of the first elongate material 808(1) is connected to the flexible hinge 802(1). Similarly, the second end of the spring 806 is connected to the second elongate material 808(2), and an opposite end of the second elongate material 808(2) is connected to flexible hinge 802(2). The elongate material 808 can be manifest as various materials, such as a metal wire, metal cable, and/or polymer fiber, among others. The elongate material 808 can follow a path that is determined by bumpers, guides, and/or pulleys, which are not shown to avoid clutter on the drawing page.

In this implementation, the elongate material 808 can function as the member 252 that moves linearly in a manner that corresponds to the angular orientation of the first and second portions 102 and 104. In this case, the sensor 254 can be positioned relative to elongate material 808. The sensor 254 can entail element 256 that travels with the elongate material 808 and element 258 that is stationary. In the illustrated example, the sensor is positioned relative to a portion of the elongate material 808 that is orthogonal or perpendicular to the hinge axis (e.g., the y reference axis). However, other locations and linear directions of movement are contemplated. One example location is indicated generally at 810 (FIGS. 8A and 8B) where the sensor could be positioned relative to a portion of the elongate material 808 that is running generally parallel to the hinge axis (e.g., y reference axis). Other examples can sense linear movement that is neither parallel nor perpendicular to the hinge axis, but instead forms an oblique angle relative to the hinge axis. For instance, as mentioned above the path of the elongate material 808 can be determined by bumpers, guides, and/or pulleys. These elements could define a part of the path for the elongate material that forms an oblique angle relative to the hinge axis. Some implementations can sense this oblique linear movement to determine the hinge angle.

In the illustrated example, element 256 includes six evenly spaced sub-elements (shown but not individually designated on FIGS. 8A and 8B, shown and individually designated on FIGS. 9A and 9B as sub-elements 256(1)-256(6)). Individual sub-elements of element 256 can be sensed and distinguished by element 258. Thus, each sub-element can correspond to 30 degrees of angular orientation. In the 180-degree orientation of FIGS. 8A and 9A, the right-most sub-element 256(6) is proximate to and sensed by element 258. This sensed information indicates that the first and second portions are at a corresponding angle between 180 and 150 degrees, in this example.

As the first and second portions 102 and 104 are rotated toward the closed orientation, the flexible hinge 802 overcomes the spring bias and pulls the elongate material 808 (and sensor element 256) to the right in the second portion on the drawing pages as indicated by arrow 902 on FIG. 9B. As the rotation continues, each of the sub-elements 256(1)-256(6) moves linearly with the elongate material 808 and is in turn proximate to element 258. In FIGS. 8B and 9B at the closed or zero-degree orientation, the left-most sub-element 256(1) is proximate to element 258, which indicates that the corresponding angle of the first and second portions is now between zero and 30 degrees. Thus, employing the sensor 254 allows the angle of the device portions to be determined based upon the linear position of the member 252. While only the 180-degrees open and closed angles are shown, the use of the sensor can determine the intervening angles in a similar manner. This sensor configuration also lends itself to sensing other angle ranges, such as zero to 360 degrees.

While six sensor sub-elements are shown and described, any number of sub-elements could be employed. For instance, eighteen sub-elements could be employed to produce 10 degrees of granularity. Other sensor implementations are described above where the sensor provides finer hinge angle approximations based upon a signal generated between the two sensor elements 256 and 258.

Various example hinge assemblies and sensors are described that sense linear movement to determine corresponding hinge angle. Individual device elements can be made from various materials, such as metals, plastics, and/or composites. These materials can be prepared in various ways, such as from formed sheet metals, die cast metals, machined metals, 3D printed materials, molded or 3D printed plastics, and/or molded or 3D printed composites, among others, and/or any combination of these materials and/or preparations can be employed. Various hinge configurations that include a member that moves linearly corresponding to hinge angle are described. Other hinge configurations are contemplated. Specific sensor configurations are described and other sensor configurations are contemplated for sensing the linear movement of the member. For instance, capacitive sensing with a comb structure could be employed. Another example could employ a force sensor to measure torque. A magnetic sensor on a printed wiring board could be employed. Optical measurement offers still another type of sensing that could be employed.

The present hinge and linear sensing concepts can be utilized with any type of device, such as but not limited to notebook computers, smart phones, wearable smart devices, tablets, and/or other types of existing, developing, and/or yet to be developed devices.

Various methods of manufacture, assembly, and/or use for hinge assemblies and sensors are contemplated beyond those shown above relative to FIGS. 1A-9B.

Although techniques, methods, devices, systems, etc., pertaining to sensing linear movement to determine hinge angle are described in language specific to structural features and/or methodological acts, it is to be understood that the subject matter defined in the appended claims is not limited to the specific features or acts described. Rather, the specific features and acts are disclosed as example forms of implementing the claimed methods, devices, systems, etc.

Various examples are described above. Additional examples are described below. One example includes a device comprising a first portion secured to a first hinge arm that is configured to rotate around a first hinge axis and a second portion secured to a second hinge arm that is configured to rotate around a second hinge axis, a controller positioned on a central shaft that is located between the first hinge axis and the second hinge axis and is configured to be moved linearly along the central shaft by rotation of the first and second portions, and a sensor configured to sense linear movement of the controller along the central shaft to determine an orientation of the first and second portions.

Another example can include any of the above and/or below examples where the controller comprises a timing shuttle and wherein the sensor comprises a first sensor element positioned on the timing shuttle and configured to move linearly with the controller and a second sensor element that is in a fixed position proximate to the timing shuttle.

Another example can include any of the above and/or below examples where the device further comprises a cradle that guides the linear movement of the controller, and wherein the second sensor element is positioned relative to the cradle.

Another example can include any of the above and/or below examples where the second sensor element is positioned on the cradle or suspended from the cradle.

Another example can include any of the above and/or below examples where a hinge cover protects a spine of the device and wherein the second sensor element is positioned relative to the hinge cover.

Another example can include any of the above and/or below examples where the second sensor is positioned on the hinge cover or suspended from the hinge cover.

Another example includes a device comprising a first portion including a first display and a second portion including a second display, a hinge assembly rotationally securing the first and second portions through a range of angular orientations; the hinge assembly comprising a member that is configured to move linearly responsive to rotation of the first and second portions, a sensor positioned relative to the member and configured to sense a relative linear position of the member, and a processor configured to receive the relative linear position from the sensor and map the relative linear position to an individual angular orientation of the first and second portions.

Another example can include any of the above and/or below examples where the member is configured to move linearly parallel to a hinge axis defined by the hinge assembly, or wherein the member is configured to move perpendicular to the hinge axis, or wherein the member is configured to move linearly along an axis that forms an oblique angle relative to the hinge axis.

Another example can include any of the above and/or below examples where the member comprises a biasing structure that is oriented perpendicular to a hinge axis defined by the hinge assembly.

Another example can include any of the above and/or below examples where the member comprises a controller that is configured to move linearly on a central shaft that is parallel and between two hinge axes defined by the hinge assembly.

Another example can include any of the above and/or below examples where the member comprises a hinge arm that rotates around a hinge axis defined by the hinge assembly and wherein the first portion is slideably secured to the hinge arm and wherein a first sensor element is positioned on the hinge arm and a second sensor element is positioned on the first portion to collectively detect sliding between the first portion and the hinge arm.

Another example can include any of the above and/or below examples where the processor comprises a microcontroller or wherein the processor comprises a central processing unit.

Another example can include any of the above and/or below examples where the sensor comprises a first element positioned on the member and a second element that is configured to contact the first element or wherein the second element is positioned proximate to the first element but does not contact the first element.

Another example can include any of the above and/or below examples where the first element positioned on the member comprises a comb pattern and the second element comprises capacitive sensing pads.

Another example includes a device comprising a first portion including a display and a second portion including an input device, a hinge assembly rotationally securing the first and second portions through a range of angular orientations, and a sensor positioned relative to the hinge assembly and configured to sense relative linear positions of the hinge assembly that correspond to angular orientations of the first and second portions.

Another example can include any of the above and/or below examples where the hinge assembly defines a first hinge axis that the first portion rotates around and a second hinge axis that the second portion rotates around.

Another example can include any of the above and/or below examples where the hinge assembly defines a controller that synchronizes rotation of the first portion around the first hinge axis with simultaneous and equal but opposite rotation of the second portion around the second hinge axis.

Another example can include any of the above and/or below examples where the controller is configured to travel linearly parallel to the first and second hinge axes.

Another example can include any of the above and/or below examples where the sensor is configured to sense linear movement of the controller parallel to the first and second hinge axes.

Another example can include any of the above and/or below examples where the hinge assembly comprises a member that extends perpendicular to the first hinge axis into the first portion and the sensor is configured to detect relative linear movement between the member and the first portion, or wherein the hinge assembly comprises a member that moves at an oblique angle relative to the first hinge axis and the sensor is configured to detect relative linear movement of the member.

1. A device, comprising:
a first portion secured to a first hinge arm that is configured to rotate around a first hinge axis and a second portion secured to a second hinge arm that is configured to rotate around a second hinge axis;
a controller positioned on a central shaft that is located between the first hinge axis and the second hinge axis and is configured to be moved linearly along the central shaft by rotation of the first and second portions; and,
a sensor configured to sense linear movement of the controller along the central shaft to determine an orientation of the first and second portions.

2. The device of claim 1, wherein the controller comprises a timing shuttle and wherein the sensor comprises a first sensor element positioned on the timing shuttle and configured to move linearly with the controller and a second sensor element that is in a fixed position proximate to the timing shuttle.

3. The device of claim 2, further comprising a cradle that guides the linear movement of the controller, and wherein the second sensor element is positioned relative to the cradle.

4. The device of claim 3, wherein the second sensor element is positioned on the cradle or suspended from the cradle.

5. The device of claim 2, further comprising a hinge cover that protects a spine of the device and wherein the second sensor element is positioned relative to the hinge cover.

6. The device of claim 5, wherein the second sensor element is positioned on the hinge cover or suspended from the hinge cover.

7. A device, comprising:
a first portion including a first display and a second portion including a second display;
a hinge assembly rotationally securing the first and second portions through a range of angular orientations, the hinge assembly comprising a member that is configured to move linearly responsive to rotation of the first and second portions;
a sensor positioned relative to the member and configured to sense a relative linear position of the member; and,
a processor configured to receive the relative linear position from the sensor and map the relative linear position to an individual angular orientation of the first and second portions.

8. The device of claim 7, wherein the member is configured to move linearly parallel to a hinge axis defined by the hinge assembly, or wherein the member is configured to move perpendicular to the hinge axis, or wherein the member is configured to move linearly along an axis that forms an oblique angle relative to the hinge axis.

9. The device of claim 7, wherein the member comprises a biasing structure that is oriented perpendicular to a hinge axis defined by the hinge assembly.

10. The device of claim 7, wherein the member comprises a controller that is configured to move linearly on a central shaft that is parallel to and between two hinge axes defined by the hinge assembly.

11. The device of claim 7, wherein the member comprises a hinge arm that rotates around a hinge axis defined by the hinge assembly and wherein the first portion is slideably secured to the hinge arm and wherein a first sensor element is positioned on the hinge arm and a second sensor element is positioned on the first portion to collectively detect sliding between the first portion and the hinge arm.

12. The device of claim 7, wherein the processor comprises a microcontroller or wherein the processor comprises a central processing unit.

13. The device of claim 7, wherein the sensor comprises a first sensor element positioned on the member and a second sensor element that is configured to contact the first sensor element or wherein the second sensor element is positioned proximate to the first sensor element but does not contact the first sensor element.

14. The device of claim 13, wherein the first sensor element positioned on the member comprises a comb pattern and the second sensor element comprises capacitive sensing pads.

15. A device, comprising:
a first portion including a display and a second portion including an input device;
a hinge assembly rotationally securing the first and second portions through a range of angular orientations; and,
a sensor positioned relative to the hinge assembly and configured to sense relative linear positions of the hinge assembly that correspond to angular orientations of the first and second portions.

16. The device of claim 15, wherein the hinge assembly defines a first hinge axis that the first portion rotates around and a second hinge axis that the second portion rotates around.

17. The device of claim 16, wherein the hinge assembly defines a controller that synchronizes rotation of the first portion around the first hinge axis with simultaneous and equal but opposite rotation of the second portion around the second hinge axis.

18. The device of claim 17, wherein the controller is configured to travel linearly parallel to the first and second hinge axes.

19. The device of claim 18, wherein the sensor is configured to sense linear movement of the controller parallel to the first and second hinge axes.

20. The device of claim 19, wherein the hinge assembly comprises a member that extends perpendicular to the first hinge axis into the first portion and the sensor is configured to detect relative linear movement between the member and the first portion, or wherein the hinge assembly comprises a member that moves at an oblique angle relative to the first hinge axis and the sensor is configured to detect relative linear movement of the member.
